(19) United States
(12) Patent Application Publication
(10) Pub. No.: US 2013/0020607 A1
(43) Pub. Date: Jan. 24, 2013

(54) LED MODULE AND METHOD FOR MANUFACTURING THE SAME

(71) Applicants: HSIN-CHIANG LIN, Hukou (TW); WEN-LIANG TSENG, Hukou (TW)

(72) Inventors: HSIN-CHIANG LIN, Hukou (TW); WEN-LIANG TSENG, Hukou (TW)

(73) Assignee: ADVANCED OPTOELECTRONIC TECHNOLOGY, INC., Hsinchu Hsien (TW)

(21) Appl. No.: 13/337,127

(22) Filed: Dec. 25, 2011

(30) Foreign Application Priority Data
Jul. 21, 2011 (CN) 201110205141.3

(51) Int. Cl. H01L 33/64; H01L 33/52

(52) U.S. Cl. 257/99; 438/26; 257/E33.058; 257/E33.059

(57) ABSTRACT

An LED (light emitting diode) module includes a circuit board and a plurality of LEDs mounted on the circuit board. The circuit board includes a support layer, an insulative layer and a conductive layer sequentially stacked on each other. The circuit board is embossed to form a plurality of pleats on top and bottom surfaces thereof, to thereby increase heat dissipation area of the circuit board.

### BACKGROUND

1. Technical Field

The present disclosure relates to LED (light emitting diode) modules and methods for manufacturing the LED modules, and more particularly, to an LED module having improved heat dissipation and a method for manufacturing the LED module.

2. Description of Related Art

As a new type of light source, LEDs are widely used in various applications. However, heat is generated by the LEDs during emitting light. The heat may cause malfunction of the LEDs if it cannot be timely dissipated.

What is needed, therefore, is an LED module and a method for manufacturing the LED module which can overcome the limitations described above.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a cross section of an LED module in accordance with a first embodiment of the present disclosure.

FIG. 2 is a top view of the LED module of FIG. 1.

FIG. 3 is a cross section of an LED module in accordance with a second embodiment of the present disclosure.

### DETAILED DESCRIPTION OF THE EMBODIMENTS

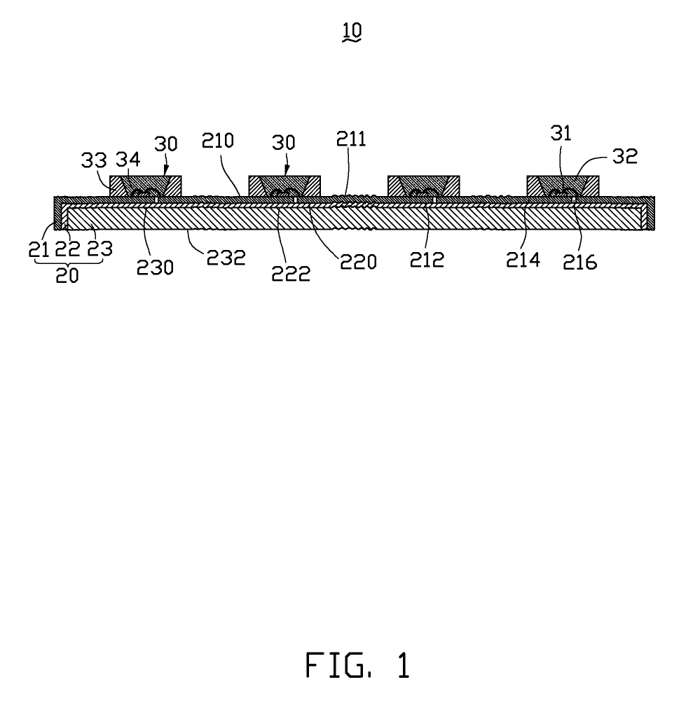

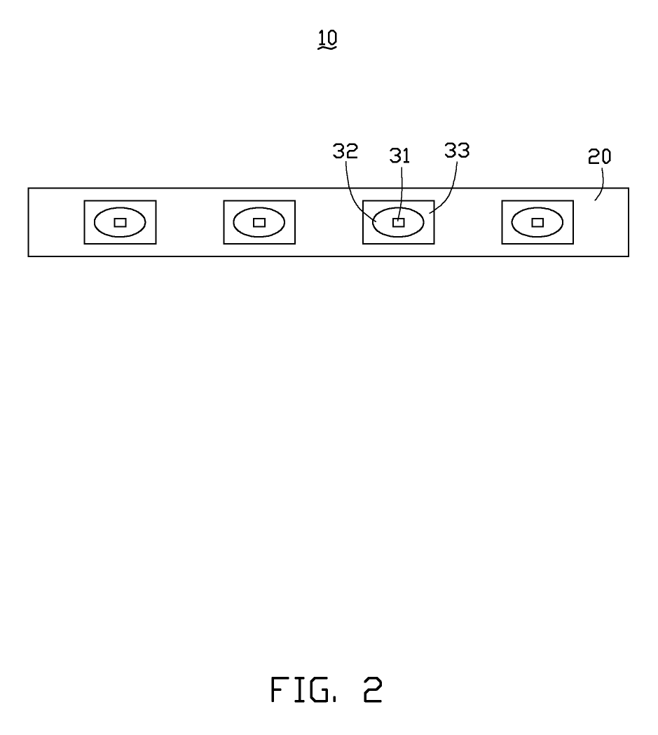

Referring to FIGS. 1-2, an LED (light emitting device) module 10 in accordance with a first embodiment of the present disclosure is shown. The LED module 10 includes a circuit board 20 and a plurality of LEDs 30 mounted on the circuit board 20.

The circuit board 20 includes a support layer 23, an insulative layer 22 formed on the support layer 23 and a conductive layer 21 formed on the insulative layer 22. The support layer 23 may be a thin metal sheet or other flexible materials so that the support layer 23 is deformable under an external force. In this embodiment, the support layer 23 is a thin aluminum sheet. The support layer 23 includes a top face 230 and a bottom face 232 opposite to the top face 230. The insulative layer 22 may be made of electrically-insulative materials such as polyimide or silicon. The insulative layer 22 is thinner than the support layer 23. The insulative layer 22 is also deformable when subject to an external force. The insulative layer 22 includes a bottom face 222 connected to the top face 230 of the support layer 23 and a top face 220 opposite to the bottom face 222.

The conductive layer 21 may be made of electrically-conductive materials such as aluminum, copper, silver or the like. The conductive layer 21 is thicker than the insulative layer 22 but thinner than the support layer 23. In this embodiment, the thickness of the conductive layer 21, the insulative layer 22 and the support layer 23 are 35 μm, 25 μm and 300 μm, respectively. The conductive layer 21 is also deformable when an external force is applied thereto. The conductive layer 21 has a bottom face 212 connected to the top face 220 of the insulative layer 22 and a top face 210 exposed. The conductive layer 21 consists of a plurality of successive sections 214 spaced from each other by gaps 216. The conductive layer 21 together with the insulative layer 22 and the support layer 23 are embossed to form a plurality of pleated regions 211. Each pleated region 211 includes a plurality of pleats. The pleats are formed on the top faces 210, 220, 230 and the bottom faces 212, 222, 232 of the conductive layer 21, the insulative layer 22 and the support layer 23. In this embodiment, there are five pleated regions 211 on the circuit board 20, wherein sizes and densities of the pleats gradually increase from two outermost pleated regions 211 near two opposite ends of the circuit board 20 towards a central pleated region 211 of the circuit board 20.

The LEDs 30 are mounted on the conductive layer 21. Each LED 30 includes a housing 33, a light emitting chip 31 received in the housing 33, two wires 34 electrically connecting the chip 31 with the conductive layer 21 and an encapsulant 32 sealing the chip 31 and the wires 34. The housing 33 defines a cavity (not labeled) in a central area thereof to receive the chip 31. The housing 33 is directly molded to the top face 210 of the conductive layer by injection-molding. The housing 33 spans two adjacent sections 214 of the conductive layer 21. The chip 31 is directly bonded on the top face 210 of a corresponding section 214 of the conductive layer 21. The chip 31 emits light when being powered. The two wires 34 directly connect the chip 31 with the two adjacent sections 214 of the conductive layer 21. The encapsulant 32 fills the cavity and seals the chip 31 and the wires 34 by injection-molding. Each LED 30 is located between two adjacent pleated regions 211.

Since the circuit board 20 forms a large amount of pleats on the bottom faces 212, 222, 232 and top faces 210, 220, 230 of the conductive layer 21, the insulative layer 22 and the support layer 23, a total surface area of the circuit board 20 is increased, whereby a heat dissipation area of the circuit board 20 is increased accordingly. Thus, heat generated by the LEDs 30 can be dissipated more rapidly by the circuit board 20. Furthermore, since the pleats are larger at the central area than at the lateral areas of the circuit board 20, the heat concentration area of the circuit board 20, i.e., the center of the circuit board 20, can have more surface areas to dissipate heat therefrom. Therefore, the LEDs 30 mounted on the circuit board 20 can operate more stably due to such an optimal distribution of the pleats on the circuit board 20.

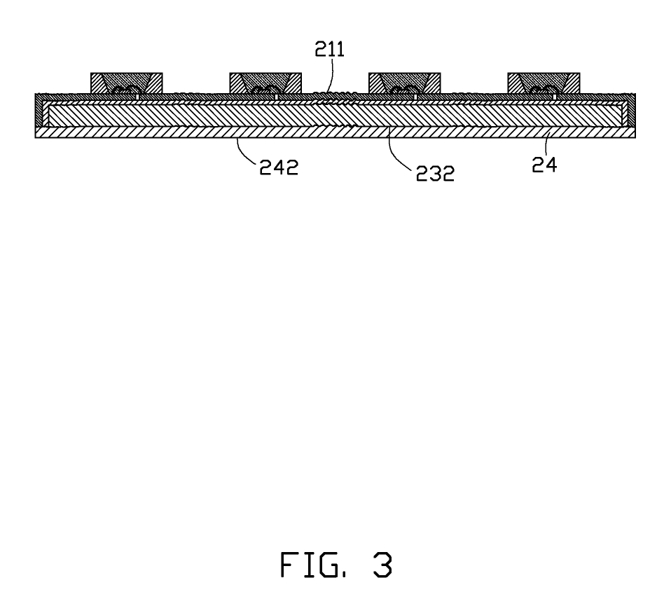

Alternatively, as shown in FIG. 3, a substrate 24 may be further attached to the bottom face 232 of the support layer 23 after the circuit board 20 is embossed to form the pleats 211. Thus, the circuit board 20 is reinforced and therefore has a certain strength to resist an outside impact. The substrate 24 may be made of rigid material which is difficult to be deformed, such as ceramic. The substrate 24 has a thickness larger than that of the conductive layer 22 and smaller than that of the support layer 23. A bottom face 242 of the substrate 24 is flat without forming any pleat thereon.

It is believed that the present disclosure and its advantages will be understood from the foregoing description, and it will be apparent that various changes may be made thereto without departing from the spirit and scope of the present disclosure or sacrificing all of its material advantages, the examples hereinbefore described merely being preferred or exemplary embodiments.

What is claimed is:

1. An LED (light emitting diode) module comprising:
a circuit board comprising an insulative layer and a conductive layer formed on the insulative layer; and
an LED mounted on and electrically connected to the conductive layer;
wherein the circuit board has an uneven surface formed thereon around the LED for increasing heat dissipation area of the circuit board to thereby help heat dissipation of the LED through the circuit board.

2. The LED module of claim 1, wherein the uneven surface comprises a plurality of pleats.

3. The LED module of claim 2, wherein the plurality of pleats are distributed on a top face of the conductive layer, the LED being mounted on the top face of the conductive layer.

4. The LED module of claim 3, wherein the circuit board further comprises a plurality of pleats distributed at an interface between the conductive layer and the insulative layer.

5. The LED module of claim 2, wherein the circuit board further comprises a support layer connected to the insulative layer, the insulative layer being sandwiched between the conductive layer and the support layer.

6. The LED module of claim 5, wherein the circuit board further comprises a plurality of pleats distributed on a bottom face of the support layer.

7. The LED module of claim 5, wherein the circuit board further comprises a plurality of pleats distributed on an interface between the insulative layer and the support layer.

8. The LED module of claim 2, wherein a density of the pleats at a central area of the circuit board is larger that than that at a distal end of the circuit board.

9. The LED module of claim 2, wherein a size of the pleats at a central area of the circuit board is larger than that at a distal end of the circuit board.

10. The LED module of claim 5, wherein the circuit board further comprises a substrate attached to the support layer, the substrate being more rigid than the conductive layer, the insulative layer and the support layer.

11. The LED module of claim 1, wherein the LED comprises a chip fixed on the conductive layer, a housing connected to the conductive layer and surrounding the chip and an encapsulant filling in the housing and sealing the chip, the chip being electrically connected to the top face of the conductive layer by wire-bonding.

12. A method for manufacturing an LED (light emitting diode) module, comprising:
providing a circuit board having an LED mounted thereon, the circuit board comprising a support layer, an insulative layer and a conductive layer sequentially stacked on each other;
embossing the circuit board to form a plurality of pleats around the LED, the plates increasing heat dissipation area of the circuit board.

13. The method of claim 12, wherein the pleats are distributed at different areas of the circuit board, size of the pleats at a central area of the circuit board being larger than that at a distal area of the circuit board.

14. The method of claim 12, wherein the pleats are distributed on a top face of the conductive layer, an interface between the conductive layer and the insulative layer, an interface between the insulative layer and the support layer, and a bottom face of the support layer.

15. The method of claim 12 further comprising attaching a substrate on a bottom face of the support layer after embossing the circuit board.

16. The method of claim 15, wherein the substrate is more rigid than the conductive layer, the insulative layer and the support layer.

17. The method of claim 12, wherein the LED comprises a chip directly secured on a top face of the conductive layer, a housing molded on the top face of the conductive layer and surrounding the chip and an encapsulant received in the housing and sealing the chip.
